(19) United States
(12) Patent Application Publication
(10) Pub. No.: US 2020/0115584 A1
(43) Pub. Date: Apr. 16, 2020

(54) A SUBSTRATE WITH A POLAR ELASTOMER DIELECTRIC AND A METHOD OF COATING A SUBSTRATE WITH A POLAR ELASTOMER DIELECTRIC

(71) Applicant: CORNING INCORPORATED, CORNING, NY (US)

(72) Inventors: Robert George Manley, Vestal, NY (US); Karan Mehrotra, Painted Post, NY (US); Barry James Paddock, Horseheads, NY (US); Rajesh Vaddi, Corning, NY (US); Nikolay Zhelev Zhelev, Painted Post, NY (US); Bin Zhu, Ithaca, NY (US)

(21) Appl. No.: 16/471,471

(22) PCT Filed: Dec. 19, 2017
(86) PCT No.: PCT/US2017/067249

§ 371 Date: Jun. 19, 2019

Related U.S. Application Data
(60) Provisional application No. 62/510,973, filed on May 25, 2017.
(60) Provisional application No. 62/436,100, filed on Dec. 19, 2016.

(51) Int. Cl. C09D 127/20; B05D 1/00; H01L 51/00

(52) U.S. Cl. CPC C09D 127/20; B05D 1/005; H01L 51/052; H01L 51/004; H01L 51/0003; H01L 51/0043

(57) ABSTRACT

A polar elastomer dielectric layer is formed on a substrate by dynamically dispensing a solution containing the polar elastomer on the substrate and curing it at an elevated temperature. The polar elastomer can include poly(vinylidene fluoride-co-hexa-fluoropropylene) (e-PVDF-HFP). They dynamic dispensing process can include spinning the substrate at a first speed, depositing the polar elastomer solution on the substrate, and spinning the substrate at a second speed.

### CROSS-REFERENCE TO RELATED PATENT APPLICATIONS

This application claims the benefit of priority under 35 U.S.C. § 119 of U.S. Provisional Application Ser. No. 62/436,100, filed on Dec. 19, 2016 and U.S. Provisional Application Ser. No. 62/510,973, filed on May 25, 2017, the contents of each are relied upon and incorporated herein by reference in their entirety.

### BACKGROUND

Transistors are the fundamental building block in modern circuitry, and are used as either signal amplifiers or on/off switches. One type of transistor is a field effect transistor. The field effect is a phenomenon in which the conductivity of a semiconductor changes due to the application of an electric field normal to its surface. The electric field is applied via a metallic gate in the device.

An organic field-effect transistor (OFET) is a field-effect transistor that uses an organic semiconductor in its channel. It can also use organic polymers such as poly(methyl-methacrylate) (PMMA) as the dielectric. These devices have been used to realize low-cost, large-area electronic products and biodegradable electronics.

The interest in OFETs has grown enormously in the past ten years. The reasons for this surge of interest are manifold. The performance of OFETs have improved significantly. As a result, there is now greater industrial interest in using OFETs for applications that are currently incompatible with the use of a-Si or other inorganic transistor technologies. One of their main technological attractions is that all the layers of an OFET can be deposited and patterned at room temperature, which makes them ideally suited for realizing low-cost, large-area electronic functions on flexible substrates.

Although they hold tremendous potential, it has been challenging to produce OFETs that have high transconductance. This is difficult to achieve with organic materials due to their relatively low charge carrier mobilities. One way to produce high transconductance is using dielectric layers having high capacitances. Recent research has shown that polar elastomers can be used to make high capacitance dielectric layers, especially polar elastomers that exhibit a double-layer capacitance effect such as poly(vinylidene fluoride-cohexafluoropropylene)(e-PVDF-HFP).

The conventional method for forming a polar elastomer dielectric layer is to place a puddle of a solution containing the polar elastomer in the middle of a stationary substrate and then spin the substrate until the polar elastomer coats it. Unfortunately, this method has many problems. One problem is that it doesn't produce a layer of uniform thickness. The thickness can vary substantially across the substrate. Another problem is that it is only really suitable for small diameter substrates such as those that are up to about an inch in diameter.

### SUMMARY

A method for making an organic field effect transistor (OFET) includes dynamically dispensing a polar elastomer dielectric on a substrate. The method can be used with any OFET including organic thin film transistors (OTFTs) such as those used in organic light emitting devices (OLEDs). The method facilitates the high quantity production of OFETs.

The method provides a number of advantages. One advantage is that it can be used to produce a dielectric layer of uniform thickness across the surface of the substrate. For example, in some embodiments, the thickness of the dielectric layer varies less than ±25%. Another advantage is that the method can be used to coat larger substrates including those that are greater than 2 inches in width.

The method can use any suitable type of polar elastomer. In some embodiments, the polar elastomer has a high static capacitance and/or exhibits a double layer capacitance effect. Examples of suitable polar elastomers include fluoroelastomers such as poly(vinylidene fluoride-co-hexafluoropropylene) (e-PVDF-HFP).

The substrate can be any suitable material capable of being coated with a dielectric layer. Examples of suitable substrates include glass, ceramic glass, silicon, organic semiconductors, and the like. The substrate can be a homogeneous surface or it can be made of a combination of one or more other layers such as, for example, an organic semiconductor layer recessed in silicon.

It should be understood the width of the substrate refer to the largest dimension measured across the surface of the substrate. Therefore, the substrate can have any suitable shape such as round, roughly round, polygonal, or the like, and the width of the substrate can be determined by identifying and measuring the largest dimension across the surface. The width is the same as the diameter of the substrate in those situations where the substrate is round or roughly round.

The Summary is provided to introduce a selection of concepts in a simplified form that are further described below in the Detailed Description. The Summary and the Background are not intended to identify key concepts or essential aspects of the disclosed subject matter, nor should they be used to constrict or limit the scope of the claims. For example, the scope of the claims should not be limited based on whether the recited subject matter includes any or all aspects noted in the Summary and/or addresses any of the issues noted in the Background.

### DRAWINGS

The preferred and other embodiments are disclosed in association with the accompanying drawings in which:

FIG. 1 shows one embodiment of an organic field effect transistor.

FIG. 2 is an image of a 150 mm silicon wafer coated with a 900 nm thick layer of polar elastomer.

FIG. 3 is a thickness map of a 150 mm silicon wafer coated with a polar elastomer using a dynamic dispensing method.

FIG. 4 is an image of the roughness of a silicon wafer coated with a polar elastomer using a dynamic dispensing method.

FIG. 5 is a graph showing that different spin speeds can be used to produce different dielectric layer thicknesses.

FIG. 6 is an graph showing the results of a thermal stability test on the polar elastomer dielectric layer.

FIG. 7 is a thickness map of a 150 mm silicon wafer coated with a polar elastomer using a conventional puddling dispensing method.

### DETAILED DESCRIPTION

A method is disclosed for coating a substrate with a polar elastomer dielectric layer to produce organic field effect transistors (OFETs). OFETs generally include three electrodes or terminals, the source, drain, and gate, as well as an organic semiconductor layer and an insulating or dielectric layer positioned between the organic semiconductor and the gate electrode. These components can be configured in a variety of ways to product different types of OFETs.

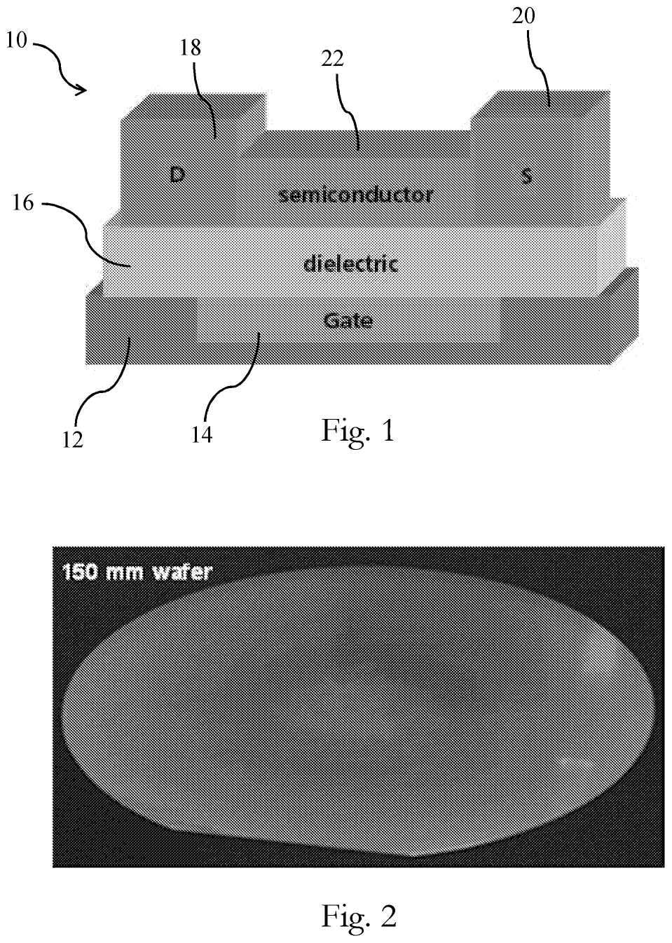

FIG. 1 shows one example of an OFET 10 that is configured as an organic thin film transistor (OTFT). The OFET includes a base layer or substrate 12, a gate electrode 14, a dielectric layer 16, a drain electrode 18, a source electrode 20, and an organic semiconductor 22. The gate electrode 14 is positioned in a recess in the base layer 12. The dielectric layer 16 is positioned on top of the base layer 12 and the gate electrode 14. The drain and source electrodes 18, 20 are positioned on top of the dielectric layer 16 on the left and right sides, respectively. The organic semiconductor layer 22 is positioned on top of the dielectric layer 16 between the drain and source electrodes 18, 20.

It should be appreciated that FIG. 1 is only one example of an OFET that can be made using the described method. Numerous other configurations can also be made including those used with organic light emitting devices (OLEDs) such as AMOLED displays and the like.

The OFET operates as follows. A voltage is applied to the gate 14 to control the amount of current flow between the source 20 and the drain 18. In a p-type OFET, a negative voltage greater in magnitude than the threshold voltage of the semiconductor material 22 is applied between the gate 14 and the source 20. This voltage causes a p-type channel to form at the semiconductor-insulator interface. A negative voltage is also applied between the drain 18 and the source 20, causing holes to flow from the source 20 to the drain 18. This behavior is equivalent to a negative current flowing from the drain 18 to the source 20. In the case of an n-type OFET, the current-voltage behavior is similar, but the electrons and holes have the opposite charge.

The OFET 10 can be made of any suitable material. For example, the base layer 12 can be made of silicon, glass ceramic, or glass. The electrodes 14, 18, 20 can also be any suitable material and have any suitable configuration. In general, for an OFET to function properly, charge injection from the electrode should to be efficient. This means the work function of the electrode should match well with the energy level of the organic semiconductor such that the energy barrier for charge injection is low. Suitable materials that can be used as the electrodes include Au, Pd, indium tin oxide, and the like. Solution processable electrode materials are desirable to facilitate low cost production.

Organic Semiconductors

The organic semiconductor 22 can include any suitable material. It can be a polymer and/or a non-polymer. It can also be a p-type semiconductor or an n-type semiconductor. In one embodiment, the organic semiconductor 22 includes a fused thiophene based semiconducting polymer such as, for example, a fused thiophene diketopyrrolopyrrole semiconducting polymer having the following structure:

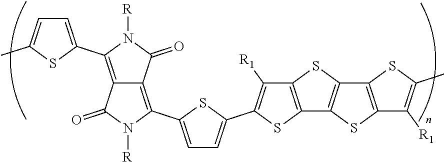

wherein R and R₁ are, independently, hydrogen or alkyl (e.g., C₁—C₃₀ alkyl). In one embodiment, the fused thiophene diketopyrrolopyrrole semiconducting polymer includes poly(tetrathienoacene-diketopyrrolopyrrole) (PTDPPTFT4) having the following structure:

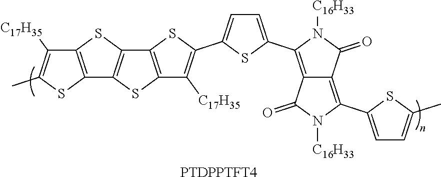

It should be appreciated that numerous other organic semiconductors 22 can be used. For example, the organic semiconductor 22 can include graphene. The organic semiconductor 22 can also include an n-type organic semiconductor polymer such as: poly(benzimidazobenzophenanthroline); poly[(2,5-didecyloxy-1,4-phenylene) (2,4,6-triisopropylphenylborane)], diphenyl terminated; poly(2,5-di(3,7-dimethyloctyloxy)cyanoterephthalylidene); poly(2,5-di(hexyloxy)cyanoterephthalylidene); poly(5-(3,7-dimethyloctyloxy)-2-methoxy-cyanoterephthalylidene); and/or poly(2,5-di(octyloxy)cyanoterephthalylidene), Poly(5-(2-ethylhexyloxy)-2-methoxy-cyanoterephthalylidene).

The organic semiconductor 22 can also include a non-polymer n-type organic semiconductor such as: bisbenzimidazo[2,1-a:2′,1′-a′]anthra[2,1,9-def 6,5,10-d′e′f]diisoquinoline-10,21-dione; 2,9-bis[2-(4-chlorophenyl)ethyl]anthra[2,1,9-def:6,5,10-d′e′f′]diisoquinoline-1,3,8,10(2H,9H)tetrone; N,N′-bis(2,5-di-tert-butylphenyl)-3,4,9,10-perylenedicarboximide; 2,9-bis[2-(4-fluorophenyl)ethyl]anthra[2, 1,9-def:6,5,10-d′e′f′]diisoquinoline-1,3,8,10(2H,9H)tetrone; 2,9-bis[(4-(methoxyphenyl)methyl]anthra[2, 1,9-def:6,5,10-d′e′f′]diisoquinoline-1,3,8,10(2H,9H)tetrone; 6,12-bis(2,3,4,5,6-pentafluorophenyl)indeno[1,2-b]fluorene; N,N′-bis(3-pentyl)perylene-3,4,9,10-bis(dicarboximide); 5,5″′-bis(tridecafluorohexyl)-2,2′:5′,2″:5″,2″′-quaterthiophene; 2,2′-bis[4-(trifluoromethyl)phenyl]-5,5′-bithiazole; 6,12-bis(2,4,6-trimethylphenyl)indeno[1,2-b]fluorene; copper(II) 1,2,3,4,8,9,10,11,15,16,17,18,22,23,24,25-hexadecafluoro-29H,31H-phthalocyanine; DBP; 1,7-dibromo-3,4,9,10-tetracarboxylic acid dianhydride; 2,9-diheptylanthra[2,1,9-def:6,5,10-d′e′f′]diisoquinoline-1,3, 8,10(2H,9H)tetrone; 2,9-dihexylanthra[2, 1,9-def. 6,5,10-d′e′f′]diisoquinoline-1,3, 8,10(2H,9H)tetrone; 2,7-dihexylbenzo[1 mn] [3, 8]phenanthroline-1,3,6, 8(2H, 7H)-tetrone; 4-(2,3-dihydro-1,3-dimethyl-1H-benzimidazol-2-yl)-N,N-dimethylbenzenamine; 4-(1,3-dimethyl-2,3-dihydro-1H-benzoimidazol-2-yl)-N,N-diphenylaniline; N,N′-dimethyl-3,4,9,10-perylenedicarboximide; N,N′-dioctyl-3,4,9,10-perylenedicarboximide; N,N′1-dipentyl-3,4,9, 10-perylenedicarboximide; [6.6] diphenyl C₆₂ bis(butyric acid methyl ester)(mixture of isomers); N,N′-diphenyl-3,4,9,10-perylenedicarboximide; 2,9-dipropylanthra[2,1,9-def 6,5,10-d′e′f]diisoquinoline-1,3,8,10(2H,9H)tetrone; N,N′-ditridecylperylene-3,4,9,10-tetracarboxylic diimide; [5,6]-fullerene-C₇₀ (95% to >99%); fullerene-C₆₀; fullerene-C₈₄; ICBA (99%-99.9%); ICMA; indeno[1,2-b]fluorene-6,12-dione; 1,4,5,8-naphthalenetetracarboxylic dianhydride; 1,2,3,4,5,6,7,8-octafluoro-9,10-bis[4-(trifluoromethyl)phenyl]anthracene; 1,2,3,4,5,6,7,8-octafluoro-9,10-bis[2-(2,4,6-trimethylphenyl)ethynyl]anthracene; perylene-3,4,9,10-tetracarboxylic dianhydride; [6,6]-phenyl-C₆₁ butyric acid butyl ester (97%-99.9%); [6,6]-phenyl C₇₁ butyric acid methyl ester (mixture of isomers); [6,6]-phenyl-C₆₁ butyric acid octyl ester; 7,7,8,8-tetracyanoquinodimethane; 2,3,5,6-tetrafluoro-7,7,8,8-tetracyanoquinodimethane; 5,10,15,20-tetrakis(pentafluorophenyl)-21H,23H-porphine palladium(II); 1,3,8,10(2H,9H)-tetraone, 2,9-bis(2-phenylethyl)anthra[2, 1, 9-def 6,5,10-d′e′f′]diisoquinoline; 1,3,6, 8(2H,7H)-tetraone, 2,7-dicyclohexylbenzo[1mn][3,8]phenanthroline; and/or [6,6]-thienyl C₆₁ butyric acid methyl ester.

The organic semiconductor 22 can also include a p-type organic semiconductor polymer such as: F8BT (e.g., average Mₙ 17,000-23,000); F8T2; MDMO-PPV; MEH-PPV (e.g., average Mₙ 40,000-250,000); PBDTBO-TPDO; PBDT(EH)-TPD(Oct); PBDT-TPD (e.g., average Mₙ 10,000-50,000); PBDTTT-CF; PBTTPD; PBTTT-C14; PCDTBT; PCPDTBT (e.g., average M_{w} 7,000-20,000); PDTSTPD; PFO-DBT (e.g., average M_{w} 10,000-50,000); poly([2,6′-4,8-di(5-ethylhexylthienyl)benzo [1,2-b ;3,3 -b] dithiophene] { 3 -fluoro-2 [(2-ethylhexyl)carbonyl]thieno [3,4-b]thiophenediyl}); poly(3-dodecylthiophene-2,5-diyl) (regioregular, regiorandom, and/or electronic grade, e.g., average M_{w} 15,000-80,000); poly(3-hexylthiophene-2,5-diyl) (regiorandom, regioregular, and/or electronic grade, e.g., average M_{w} 15,000-75,000); poly(3-octylthiophene-2,5-diyl) (regioregular, regiorandom, and/or electronic grade, e.g., average M_{w} 20,000-30,000); PSiF-DBT; PTAA (a poly(triaryl amine) semiconductor); PTB7 (e.g., average M_{w} 80,000-200,000; PDI≤3.0); and/or TQ1.

The organic semiconductor 22 can also include a non-polymer p-type organic semiconductor such as: ADT; benz[b]anthracene; benz[b]anthracene (98%-99%); 2,4-bis[4-(N,N-dibenzylamino)-2,6-dihydroxyphenyl]squaraine; 5,5″″-bis(2″″′,2″″′-dicyanovinyl)-2,2′:5′,2″:5″,2′″:5′″,2″″-quinquethiophene (DCVST); 2,4-bis[4-(N,N-diisobutylamino)-2,6dihydroxyphenyl] squaraine; 2,4-bis[4-(N,N-diphenylamino)-2,6-dihydroxyphenyl]squaraine; bis(ethylenedithio)tetrathiafulvalene; 2-[(7-{4-[N,N-bis(4-methylphenyl)amino]phenyl}-2,1,3-benzothiadiazol-4-yl)methylene]propanedinitrile; 6,13-bis((triethylsilyl)ethynyl)pentacene; 6,13-bis(triisopropylsilylethynyl)pentacene; C8-BTBT; copper(II) phthalocyanine; coronene; DH-FTTF; dibenzotetrathiafulvalene; 5,5′di(4-biphenylyl)-2,2′-bithiophene; 3,3″′-Didodecyl-2,2′:5′,2″:5″,2″′-quaterthiophene; diF-TES-ADT; 5,5′-dihexyl-2,2′-bithiophene; 3,3′″-dihexyl-2,2′:5′,2″:5″,2″′-quaterthiophene; 5,5″″′-dihexyl-2,2′:5′,2″:5″,2″′:5″′,2″″:5″″,2″″′-sexithiophene; dinaphtho[2,3-b:2′,3′-f]thieno[3,2-b]thiophene; 2-[7-(4-diphenylaminophenyl)-2, 1,3 -benzothiadiazol-4-yl]methylenepropanedinitrile; 2,6-diphenylbenzo[1,2-b:4,5-b ]dithiophene sublimed grade; 2-{7-diphenyl[1]benzothieno[3,2-b][1]benzothiophene sublimed grade; 6,13-diphenylpentacene; 24[745-N,N-ditolylaminothiophen-2-yl)-2,1,3-benzothiadiazol-4-yl]methylene}malononitrile; 2,6-ditolylbenzo[1,2-b:4,5-b]dithiophene; DTS(FBTTh₂)₂; DTS(PTTh₂)₂; FTTF; merocyanine dye, HB194; PDPP2T-TT-OD; pentacene; pentacene-N-sulfinyl-tert-butylcarbamate; platinum octaethylporphyrin; 2,2′:5′,2″:5″,2′″-quaterthiophene; rubrene; α-sexithiophene; SMDPPEH; SMDPPO; 13,6-N-sulfinylacetamidopentacene; TES-ADT; tetrathiafulvalene; tin(IV) 2,3-naphthalocyanine dichloride; and/or tris[4-(5-dicyanomethylidenemethyl-2-thienyl)phenyl]amine.

Polar Elastomer Dielectric

The dielectric layer 16 should be relatively thin, pinhole-free, and have a high dielectric constant for low voltage operation. The dielectric layer 16 can be made of any suitable polar elastomer. In general, it is desirable to use polar elastomers having high capacitances because they produce OFETs having both high gain and high transconductance. One group of polar elastomers having high capacitances are those that exhibit a double-layer capacitance effect under an applied gate voltage. It should be appreciated that polar elastomers that do not exhibit the double-layer capacitance effect can also be used depending on the application.

The polar elastomer can have any suitable static capacitance. In some embodiments, the polar elastomer has a capacitance of at least approximately 0.1 μF/cm² or at least approximately 0.2 μF/cm². In other embodiments, the polar elastomer has a capacitance of approximately 0.1 μF/cm² to approximately 0.5 μF/cm² or approximately 0.2 μF/cm² to approximately 0.4 μF/cm². As mentioned above, the higher capacitances are generally produced by the polar elastomers that exhibit a double-layer capacitance effect under an applied gate voltage.

The polar elastomer can be used to produce relatively thick dielectric layers that have high capacitances. Thick layers may be desirable in some applications to prevent voltage leakage through the dielectric layer. Unlike conventional dielectrics, where the capacitance decreases as the thickness of the dielectric layer increases, the polar elastomer has a high capacitance that is largely independent of thickness up to a certain thickness such as 2.5 μm.

In some embodiments, the polar elastomer is deposited as a layer that is at least approximately 300 nm thick, at least approximately 400 nm thick, at least approximately 500 nm thick, or at least approximately 600 nm thick. In other embodiments, the polar elastomer is no more than approximately 2.5 μm thick or no more than approximately 2.0 μm thick. In other embodiments, the polar elastomer is approximately 300 nm to approximately 2.5 μm thick or approximately 400 nm to approximately 2.0 μm thick. The dielectric layer can also have any of these thicknesses.

The polar elastomer can also exhibit relatively high levels of thermal stability, especially when formed as a dielectric layer on silicon, glass ceramic, or glass substrate. In some embodiments, the polar elastomer is thermally stable (as measured using the test described in Example 3) at temperatures of at least approximately 150° C., at least approximately 180° C., at least approximately 200° C., at least approximately 225° C., or at least approximately 250° C.

In some embodiments, the polar elastomer includes one or more fluoroelastomers. The fluoroelastomers can have any suitable physical properties. For example, the fluoroelastomer can have a fluorine percentage of approximately 65% to approximately 71%, a specific gravity of approximately 1.80 to approximately 2.0, a mooney viscosity of approximately 17 to approximately 80 (measured at 1+10@121 ° C.), a tensile strength of approximately 10 MPa to approximately 18 MPa, an elongation at break of approximately 170% to approximately 350%, a 100% modulus measurement of approximately 2.5 MPa to approximately 8.5 MPa, and hardness (Shore A) of approximately 70 to approximately 86.

Examples of suitable fluoroelastomers include di-polymers (e.g., vinylidene fluoride and hexafluoropropylene), terpolymers (e.g., vinylidene fluoride, hexafluoropropylene, and tetrafluoroethylene), perfluoroelastomers, and the like. One notable example of a fluoroelastomer is elastomeric poly(vinylidene fluoride-co-hexafluoropropylene) (e-PVDF-HFP). This material has the structure shown below and is capable of exhibiting the double-layer capacitance effect described above.

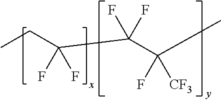

Suitable fluoroelastomers include any of 3M's Dyneon Fluoroelastomers. One example of a suitable e-PVDF-HFP is 3M's Dyneon Fluoroelastomer FC 2176 (fluorine content=65.9%; specific gravity=1.80; mooney viscosity=approximately 30; tensile strength=15.0; 100% modulus=4.1; elongation at break=240%; and hardness (shore A)=71). It is capable of producing a dielectric layer having a capacitance of approximately 0.3 μF/cm².

The polar elastomer can be crosslinked to make it more robust and chemically stable. This may be especially desirable for situations where the dielectric layer is later patterned using photolithography and the like. The polar elastomer can be crosslinked using crosslinking agents and/or by thermal curing at high temperatures (e.g., 180° C.). The surface of the polar elastomer can also be treated to alter its chemical and/or physical characteristics.

Dielectric Layer Deposition

The following method can be used to form the dielectric layer 16 on the base layer 12. It should be appreciated that although the method is described with reference to the OFET shown in FIG. 1 it can be used with a wide variety of other OFETs. The base layer 12 is only one of many different substrates that can be coated with the dielectric layer 16.

It should be appreciated that the method can be used to form a dielectric layer on any type of substrate. The dielectric layer can be formed on: (1) the underlying substrate of silicon, ceramic glass, or glass, (2) the organic semiconductor layer, and/or (3) the gate electrode(s). Examples of suitable substrates includes those made of silicon, ceramic glass, glass, organic semiconductor layer, electrode material, (these can be doped or undoped). The substrate can be a single homogenous material or a combination of different materials organized in layers such as that shown in FIG. 1. The substrate can have numerous other configurations.

The method can be used to form a dielectric layer on substrates having any suitable physical shape or dimensions. For example, it can be used to coat substrates that are round, roughly round, polygonal (triangular, square, rectangular, and the like), elliptical, oval, and the like. It can also be used to uniformly coat any size substrate. For example, it can be used to coat substrates that are at least approximately 2 inches wide, at least approximately 3 inches wide, at least approximately 4 inches wide, at least approximately 5 inches wide, or at least approximately 6 inches wide.

The method can be used to produce a coating or layer on the substrate having any desired thickness. Thicker layers (>1 μm) are advantageous because they produce a better insulating layer that is less susceptible to leakage current. The relatively high thickness may not adversely affect the operation of the dielectric layer due to the double-layer capacitance effect of certain polar elastomers. Thinner layers (≤1 μm) are advantageous because they are more suitable for flexible applications and provide increased switching speeds, which increases the gain and transconductance of the OFET.

In some embodiments, the method is used to make a coating on the substrate that is at least approximately 5 nm thick, at least approximately 10 nm thick, at least approximately 35 nm thick, at least approximately 50 nm thick, at least approximately 75 nm thick, or at least approximately 100 nm thick. In other embodiments, the method is used to make a coating on the substrate that is approximately 5 nm to approximately 2,000 nm, approximately 10 nm to approximately 1,900 nm, approximately 35 nm to approximately 1,700 nm, approximately 50 nm to approximately 1,500 nm, approximately 75 nm to approximately 1,250 nm, or approximately 100 nm to approximately 1,000 nm. In other embodiments, the method is used to make a coating on the substrate that is no more than approximately 2,000 nm thick, no more than approximately 1,900 nm thick, no more than approximately 1,700 nm thick, no more than approximately 1,500 nm thick, no more than approximately 1,250 nm thick, or no more than approximately 1,000 nm thick.

The method can be used to form a dielectric layer having uniform thickness. For example, in some embodiments, the thickness of the dielectric layer varies no more than approximately ±25%, no more than approximately ±20%, no more than approximately ±15%, or no more than approximately ±10%. The thickness of the dielectric layer can be measured using Filmetrics F50 optical measurement system with a spot size ranging from 100 μm to 10 μm square. The surface of the dielectric layer is also smooth. For example, the roughness of the dielectric layer can be no more than approximately 0.7 nm, no more than approximately 0.6 nm, or no more than approximately 0.5 nm.

A solution containing the polar elastomer is prepared by dissolving the polar elastomer in a solvent. The solution can also include crosslinking agents such as 1,3,5-Triallyl-1,3,5-triazine-2,4,6(1H,3H,5H)-trione, benzoyl peroxide, and the like. Any solvent can be used as long as it is capable of dissolving the polar elastomer. Examples of suitable solvents include ketones such as 2-butanone (methyl ethyl ketone), esters, and the like. The polar elastomer can be dissolved in the solvent using any suitable technique that completely dissolves the polar elastomer. This can take anywhere from 15 minutes to 20 hours or longer. The mixing process can be performed at ambient temperature. It can also be performed in air or in an inert atmosphere of nitrogen gas, one or more noble gases, or any combination of these gases.

The solution can have any suitable concentration of polar elastomer. In some embodiments, the concentration of polar elastomer is approximately 50 mg/ml to approximately 150 mg/ml or approximately 70 mg/ml to approximately 130 mg/ml. A general rule of thumb is that lower concentrations produce thinner dielectric layers and higher concentrations produce thicker dielectric layers. The concentration of the solution isn't the only factor that affects the thickness, however. Other factors such as spin speed also affect the thickness.

The substrate should be cleaned prior to coating. This can be done using any suitable method. For example, the substrate can be cleaned using oxygen plasma having the following characteristics: (a) power of approximately 25 watts to approximately 600 watts or approximately 50 watts to approximately 300 watts, (b) oxygen gas flow rates of approximately 2.5 sccm (standard cubic centimeter per minute) to approximately 80 sccm or approximately 5 sccm to approximately 40 sccm, and (c) process time of approximately 30 seconds to approximately 20 minutes or approximately 1 minute to approximately 10 minutes.

The substrate is coated with the polar elastomer using a dynamic dispensing method. The substrate is initially coupled to a spin coating apparatus and rotated until it reaches a first speed. This is done before the polar elastomer solution is applied. The first speed can be any suitable speed. In some embodiments, the first speed is approximately 25 rpm to approximately 600 rpm or approximately 50 rpm to approximately 300 rpm. In other embodiments, the first speed is at least approximately 25 rpm or at least approximately 50 rpm.

The polar elastomer solution is deposited in the center of the substrate while the substrate is spinning at the first speed. The spin speed of the substrate is then increased to a second speed. The centrifugal force on the solution causes it to uniformly spread across and coat the surface of the substrate. The second speed can be any suitable speed. In some embodiments, the second speed is approximately 500 rpm to approximately 5,000 rpm or approximately 1,000 rpm to approximately 3,000 rpm.

It should be appreciated that the spin speed profile of the substrate can take many forms. In some embodiments, the spin speed increases in a stepped fashion. The substrate is initially stationary and begins spinning at increasing speeds until it reaches the first speed. The substrate stays at this speed while the polar elastomer solution is deposited. Once all the polar elastomer solution has been deposited, the spin speed increases until the substrate reaches the second speed. The substrate spins at this speed until it is completely coated with the desired thickness of the polar elastomer. This example includes two steps but it should be appreciated that a stepped spin speed profile can include one step or more than two steps.

In some other embodiments, the spin speed profile increases linearly throughout the dispensing process. The substrate is initially stationary and begins spinning at an increasing rate of speed. The polar elastomer solution is deposited on the substrate once it reaches the first speed. The substrate only rotates at the first speed momentarily because its spin speed is increasing at a constant rate. The polar elastomer solution spreads across and uniformly coats the substrate. The second speed can be considered any speed at which the substrate spins after the polar elastomer solution has been deposited.

In some other embodiments, the spin speed profile increases dynamically and/or includes one or more steps. For example, the rate at which the substrate spins can change at one or more points during the spin coating process. Also, the substrate can spin at a constant speed one or more times during the process (the rate of change is zero).

The first speed is generally the speed of the substrate when the polar elastomer solution is deposited. If the speed of the substrate is changing when the solution is deposited, then the first speed is the speed when the solution initially contacts the substrate. The second speed is any speed after the solution is deposited that is higher than the first speed. In some embodiments, the second speed is at least approximately 25% higher than the first speed, at least approximately 50% higher than the first speed, or at least 75% higher than the first speed.

The coating process can be performed in ambient conditions (ambient atmosphere, ambient temperature (approximately 20° C.), etc.). The ambient atmosphere can be considered an oxidizing atmosphere due to the presence of oxygen in the air. The coating process can also be performed in an inert atmosphere of nitrogen gas, one or more noble gases, or any combination of these gases. The inert atmosphere may be desirable to prevent unwanted condensation reactions between the polar elastomer and moisture. The spin coating process can take anywhere from approximately 1 minute to approximately 20 minutes. According to one exemplary embodiment, the spin coating process takes approximately 5 minutes based on a desired thickness.

The coated substrate can be dried to evaporate any residual solvent. The substrate can be dried at any suitable temperature and for any suitable length of time. In some embodiments, the substrate is dried at ambient temperature. In other embodiments, the substrate is dried at temperatures of approximately 40° C. to approximately 100° C. or approximately 60° C. to approximately 90° C. The coated substrate can be dried for approximately 20 minutes to approximately 6 hours or approximately 1 hour to approximately 4 hours. It should be appreciated that in some embodiments the coated substrate is not dried.

The coated substrate can be cured or annealed to crosslink the polar elastomer. It should be appreciated that the substrate can be cured at any suitable temperature and for any suitable length of time. In some embodiments, the coated substrate is cured at temperatures of approximately 80° C. to approximately 190° C. In some embodiments, the coated substrate is cured for approximately 1 hour to approximately 20 hours or approximately 4 hours to approximately 8 hours.

### EXAMPLES

The following examples are provided to further illustrate the disclosed subject matter. They should not be used to constrict or limit the scope of the claims in any way.

### Example 1

A polar elastomer dielectric layer was formed on a 150 mm silicon wafer using a dynamic dispensing method. An 80 mg/ml solution of e-PVDF-HFP (3M Dyneon Fluoroelastomer FC 2176) and 2-butanone (methyl ethyl ketone) solvent was formed by mixing the ingredients and stirring for 10 hours. The wafer was cleaned with oxygen plasma before being coated.

The wafer was spin coated using the following procedure. The wafer was mounted to spin coating apparatus and rotated in an ambient air atmosphere until it reached an initial spin speed of less than 500 rpm. The solution was deposited in the center of the wafer using a pipette and the spin speed was increased to 1500-2000 rpm based the desired thickness. The wafer was allowed to spin at this speed for 1-2 minutes to form a coated wafer. The coated wafer was then dried on a hot plate at 80° C. for 2 hours to evaporate the solvent. The coated wafer was then cured or annealed at 180° C. for 6 hours to crosslink the e-PVDF-HFP.

The polar elastomer layer was 800 nm thick. FIG. 2 shows an image of the coated wafer. This example shows that the polar elastomer e-PVDF-HFP can be used to successfully coat a relatively large silicon wafer using the dynamic dispensing method.

### Example 2

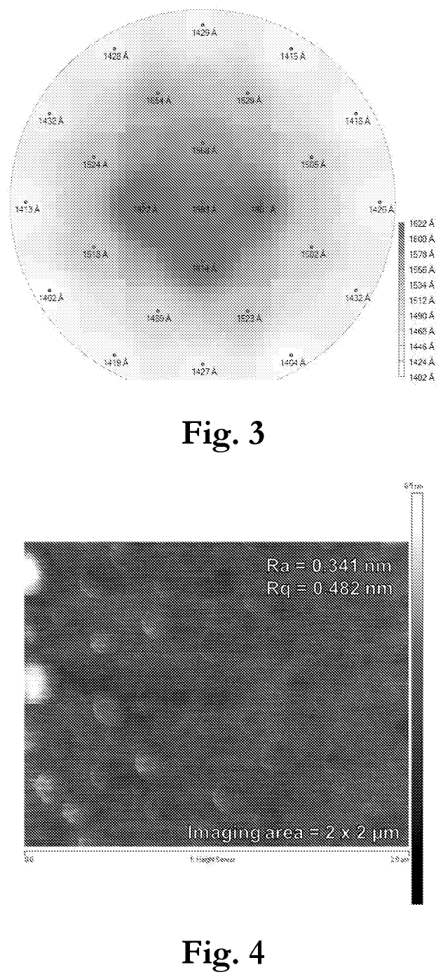

A polar elastomer dielectric layer (e-PVDF-HFP) was formed on a silicon wafer using the procedure in Example 1. Since the thermal conductivity is higher in Si than in the glass substrates, the crosslinking time may be quicker (reduced) compared to glass substrates. The thickness of the dielectric layer was mapped using a Filmetrics F50 optical measurement system. The results are shown in FIG. 3. The dark areas represent thicker portions of the layer and the light areas represent thinner portions. The thickness of the layer varied from approximately 140 nm to approximately 162 nm or approximately ±7% from an intermediate thickness of 151 nm. The roughness of the coating was also measured over a 2μm×2μm area and determined to be less than 0.5 nm as shown in FIG. 4.

The thickness of the coating is substantially more uniform than the coating produced using the puddling method described in comparative example 1. While not wishing to be bound by theory, the reason for the difference appears to be caused by condensation reactions between the elastomer particles and moisture in the puddle method. The puddling method appears to be more susceptible to these reactions than the dynamic dispensing method.

### Example 3

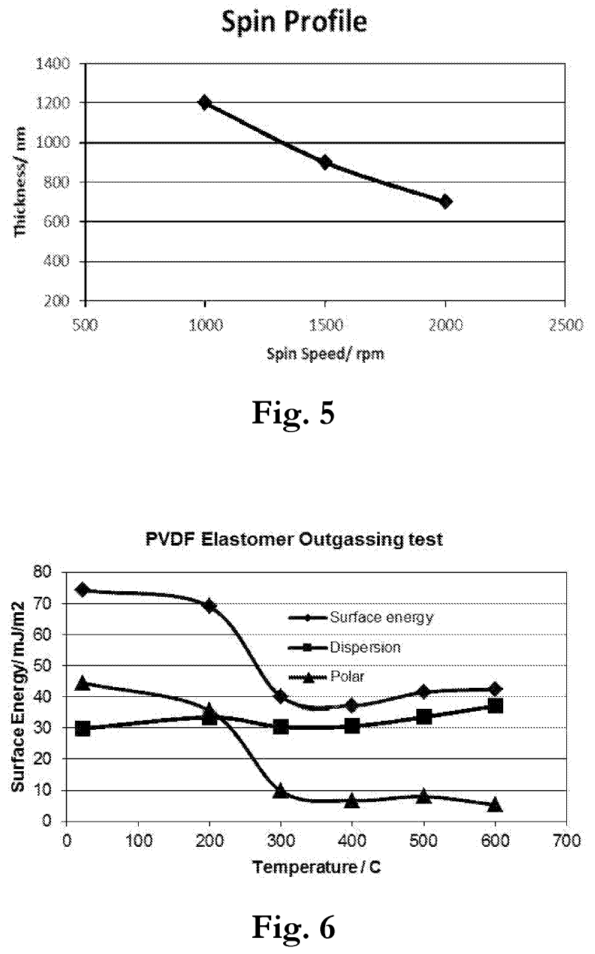

The procedure in Example 1 was repeated three times using spin speeds of 1,000 rpm, 1,500 rpm, and 2,000 rpm to produce coatings that were 1,200 nm thick, 900 nm thick, and 700 nm thick, respectively. FIG. 5 is a graph showing the relationship between the spin speed and the coating thickness. This example shows that the same polar elastomer solution (same ratio of elastomer to solvent and same viscosity) can be used to form dielectric layers having different thicknesses by adjusting the spin speed of the wafer.

### Example 4

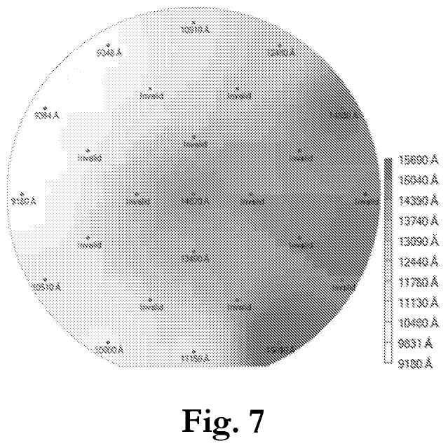

The thermal stability of the polar elastomer dielectric layer prepared in Example 1 was tested by measuring the surface energies at different temperatures ranging from 100° C. to 400° C. A fixture was made so that e-PVDF-HFP coated sample was sitting in the pocket with a bare glass piece as a top lid and subjected to different thermal treatments. The surface energies on the top lid were directly measured to illustrate whether a change in surface energy occurred, signaling a potential thermal decomposition of the e-PVDF-HFP. The test results are shown in FIG. 6. The test results show that the coating is stable up to 250° C.

### Comparative Example 1

A polar elastomer dielectric layer was formed on a 150 mm silicon wafer using the conventional puddling method. An 80 mg/ml solution of e-PVDF-HFP (3M Dyneon Fluoroelastomer FC 2176) and 2-butanone (methyl ethyl ketone) solvent was formed by mixing the ingredients and stirring for 10 hours. The wafer was cleaned with oxygen plasma before being coated.

The wafer was spin coated using the following procedure. A puddle of the polar elastomer solution was deposited in the center of the wafer while it was stationary. After all the entire solution was dispensed, the wafer was rotated until it reached a spin speed of 2000 rpm or higher based on the desired thickness. The wafer was allowed to spin at this speed for 2 minutes to form a coated wafer. The coated wafer was dried on a hot plate at 80° C. for 2 hours to evaporate the solvent. The coated wafer was then cured at 180° C. for 6 hours to crosslink the e-PVDF-HFP.

The thickness varied from approximately 918 nm to approximately 1,569 nm (thickness was mapped using a Filmetrics F50 optical measurement system). FIG. 7 shows an image representation of the resulting thickness map where the dark areas represent thicker portions of the coating and the light areas represent thinner portions of the coating. FIG. 7 shows that the thickness of the coating (or thickness uniformity of the coating) varied approximately ±28% from a halfway point of approximately 1,243 nm.

Articles such as “the,” “a,” and “an” can connote the singular or plural. Also, the word “or” when used without a preceding “either” (or other similar language indicating that “or” is unequivocally meant to be exclusive—e.g., only one of x or y, etc.) shall be interpreted to be inclusive (e.g., “x or y” means one or both x or y).

The term “and/or” shall also be interpreted to be inclusive (e.g., “x and/or y” means one or both x or y). In situations where “and/or” or “or” are used as a conjunction for a group of three or more items, the group should be interpreted to include one item alone, all the items together, or any combination or number of the items. Moreover, terms used in the specification and claims such as have, having, include, and including should be construed to be synonymous with the terms comprise and comprising.

Unless otherwise indicated, all numbers or expressions, such as those expressing dimensions, physical characteristics, and the like, used in the specification (other than the claims) are understood to be modified in all instances by the term “approximately.” At the very least, and not as an attempt to limit the application of the doctrine of equivalents to the claims, each numerical parameter recited in the specification or claims which is modified by the term “approximately” should be construed in light of the number of recited significant digits and by applying ordinary rounding techniques.

All disclosed ranges are to be understood to encompass and provide support for claims that recite any and all subranges or any and all individual values subsumed by each range. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

All disclosed numerical values are to be understood as being variable from 0-100% in either direction and thus provide support for claims that recite such values or any and all ranges or subranges that can be formed by such values. For example, a stated numerical value of 8 should be understood to vary from 0 to 16 (100% in either direction) and provide support for claims that recite the range itself (e.g., 0 to 16), any subrange within the range (e.g., 2 to 12.5) or any individual value within that range (e.g., 15.2).

The terms recited in the claims should be given their ordinary and customary meaning as determined by reference to relevant entries in widely used general dictionaries and/or relevant technical dictionaries, commonly understood meanings by those in the art, etc., with the understanding that the broadest meaning imparted by any one or combination of these sources should be given to the claim terms (e.g., two or more relevant dictionary entries should be combined to provide the broadest meaning of the combination of entries, etc.) subject only to the following exceptions: (a) if a term is used in a manner that is more expansive than its ordinary and customary meaning, the term should be given its ordinary and customary meaning plus the additional expansive meaning, or (b) if a term has been explicitly defined to have a different meaning by reciting the term followed by the phrase “as used in this document shall mean” or similar language (e.g., “this term means,” “this term is defined as,” “for the purposes of this disclosure this term shall mean,” etc.). References to specific examples, use of “i.e.,” use of the word “invention,” etc., are not meant to invoke exception (b) or otherwise restrict the scope of the recited claim terms. Other than situations where exception (b) applies, nothing contained in this document should be considered a disclaimer or disavowal of claim scope.

The subject matter recited in the claims is not coextensive with and should not be interpreted to be coextensive with any embodiment, feature, or combination of features described or illustrated in this document. This is true even if only a single embodiment of the feature or combination of features is illustrated and described.

Listing of claims:

1. A method of coating a substrate with a polar elastomer, comprising:
spinning the substrate at a first speed, wherein the first speed is greater than 0 rpm;
depositing the polar elastomer at a center of the substrate;
dispersing the polar elastomer across the substrate to form a coated substrate; and
spinning the substrate at a second speed based at least in part on the polar elastomer dispersing across the substrate.

2. The method of claim 1, wherein the second speed is greater than the first speed.

3. The method of claim 2, wherein the second speed is approximately 25% or more faster than the first speed.

4. The method of claim 1, wherein the substrate is at least three inches in diameter.

5. The method of claim 1, wherein the polar elastomer forms a coating on the substrate having a thickness that varies no more than ±25%.

6. The method of claim 1, wherein the first speed is approximately 25 rpm to approximately 600 rpm.

7. The method of claim 1, wherein the second speed is approximately 500 rpm to 5,000 rpm.

8. The method of claim 1, further comprising:
crosslinking the polar elastomer.

9. The method of claim 1, wherein the polar elastomer comprises a fluoroelastomer.

10. The method of claim 1, wherein the polar elastomer comprises poly(vinylidene fluoride-co-hexafluoropropylene) (e-PVDF-HFP).

11. The method of claim 1, wherein dispersing the polar elastomer across the substrate comprises:
dispersing the polar elastomer in an open air ambient atmosphere.

12. The method of claim 1, further comprising:
heating the coated substrate to cure the polar elastomer.

13. The method of claim 1, further comprising:
cleaning the substrate with plasma prior to coating the substrate with the polar elastomer.

14. The method of claim 1, wherein the substrate comprises at least one of silicon, glass ceramic, or glass.

15. A method of coating a substrate with a polar elastomer, comprising:
spinning the substrate at a first speed;
depositing the polar elastomer at a center of the substrate; and
dispersing the polar elastomer across the substrate to form a coated substrate,
wherein the substrate is at least three inches in diameter.

16. The method of claim 15, wherein the substrate is at least four inches in diameter.

17. The method of claim 15, wherein the polar elastomer forms a coating on the substrate having a thickness that varies no more than ±25%.

18. A substrate coated with a polar elastomer, comprising:
the substrate; and
a coating covering the substrate, the coating comprising the polar elastomer,
wherein the coating has a thickness that varies no more than ±25%.

19. The substrate of claim 18, wherein the polar elastomer comprises a fluoroelastomer.

20. The substrate of claim 18, wherein the polar elastomer comprises poly(vinylidene fluoride-co-hexafluoropropylene) (e-PVDF-HFP).
